(19) United States
(12) Patent Application Publication
(10) Pub. No.: US 2026/0357433 A1
(43) Pub. Date: Nov. 12, 2026

(54) SUBSTRATE TREATMENT METHOD AND SUBSTRATE TREATMENT SYSTEM

(71) Applicant: University of Hyogo, Hyogo (JP)

(72) Inventors: Yuki KIKUCHI, Yamanashi (JP); Seishin Yamada, Tokyo (JP); Mitsuaki Iwashita, Yamanashi (JP); Noriaki Toyoda, Hyogo (JP)

(73) Assignee: University of Hyogo, Hyogo (JP)

(21) Appl. No.: 19/707,249

(22) Filed: Jun. 13, 2026

Related U.S. Application Data
(63) Continuation of application No. PCT/JP2024/044221, filed on Dec. 13, 2024.

(30) Foreign Application Priority Data
Dec. 27, 2023 (JP) 2023-220225

(51) Int. Cl. C23C 18/16; C23C 18/44

(52) U.S. Cl. CPC C23C 18/1667; C23C 18/1628; C23C 18/1692; C23C 18/44

(57) ABSTRACT

Provided is a substrate processing method comprising: forming a metal film on a substrate by electroless plating; irradiating a surface of the substrate on which the metal film is formed with gas cluster ion beam generated by ionizing and accelerating clusters of atoms or molecules of an inert gas; and performing reduction annealing treatment on the substrate after said irradiating the substrate with the gas cluster ion beam.

### CROSS-REFERENCE TO RELATED APPLICATIONS

This application is a bypass continuation application of International Application No. PCT/JP2024/044221 having an international filing date of Dec. 13, 2024 and designating the United States, the International Application being based upon and claiming the benefit of priority from Japanese Patent Application No. 2023-220225 filed on Dec. 27, 2023, the entire contents of which are incorporated herein by reference.

### TECHNICAL FIELD

The present disclosure relates to a substrate processing method and a substrate processing system.

### BACKGROUND

International Publication No. 2019/151078 describes that, in forming embedded multilayer wiring, in a via formed in an insulating film provided on wiring, a film containing Cu, Co, Ni, or Ru is formed from the bottom surface where the wiring is exposed by electroless plating using the exposed wiring as a catalyst.

### SUMMARY

The present disclosure provides a substrate processing method and a substrate processing system capable of forming a sound, low-resistance metal film using electroless plating.

In accordance with an aspect of the subject disclosure, there is provided a substrate processing method comprising: forming a metal film on a substrate by electroless plating; irradiating a surface of the substrate on which the metal film is formed with gas cluster ion beam generated by ionizing and accelerating clusters of atoms or molecules of an inert gas; and performing reduction annealing treatment on the substrate after said irradiating the substrate with the gas cluster ion beam.

### BRIEF DESCRIPTION OF THE DRAWINGS

FIG. 1 is a schematic diagram showing a state in which cracks are generated when reduction annealing is performed after a Ru film as a metal film is formed by electroless plating.

FIG. 2 is a flowchart showing a substrate processing method according to one embodiment.

FIG. 3 is a cross-sectional view showing an example of a structure of a substrate to which the substrate processing method according to one embodiment is applied.

FIG. 4 is a cross-sectional view showing a state in which a Ru film as a metal film is embedded in a via formed in the substrate of FIG. 3 by electroless plating.

FIG. 5 is a TEM image of a Ru film when gas cluster ion beam (GCIB) using N₂ gas is irradiated onto a Ru film formed by electroless plating at an acceleration voltage of 20 kV.

FIG. 6 is a block diagram showing a substrate processing system for performing a substrate processing method according to one embodiment.

FIG. 7 is a cross-sectional view showing an example of an electroless plating apparatus included in the substrate processing system of FIG. 6.

FIG. 8 is a cross-sectional view showing an example of a GCIB irradiation apparatus included in the substrate processing system of FIG. 6.

FIG. 9 is a cross-sectional view showing an example of a reduction annealing apparatus included in the substrate processing system of FIG. 6.

### DETAILED DESCRIPTION

Hereinafter, embodiments will be described with reference to the accompanying drawings.

### <Background>

First, the background will be described.

International Publication No. 2019/151078 described above discloses formation of a film containing Cu, Co, Ni, or Ru in a via by electroless plating. Among them, Ru is attracting attention as a next-generation wiring material. Mo is also attracting attention as a next-generation wiring material. However, in the case of forming a metal film by electroless plating, oxidation is observed on the film surface and within the film in the as-deposited state. Further, a metal film formed by electroless plating is often not sufficiently crystallized in the as-deposited state, and is close to an amorphous state due to a minute grain size. Thus, the resistance of the film is high in the as-deposited state.

To address such problems, it is conceivable to perform, after the formation of a metal film by electroless plating, reduction annealing treatment on the metal film to decompose oxides and promote crystallization.

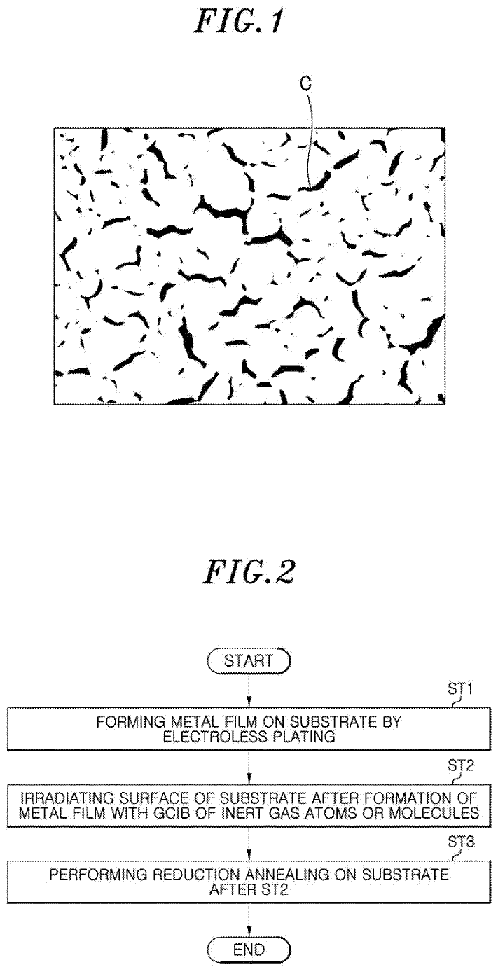

However, when reduction annealing treatment is performed on the metal film to promote crystallization, the adhesion between crystal grains decreases due to the release of oxygen from oxides between crystal grains. In this state, if significant volume shrinkage occurs due to the crystal growth from an amorphous state and tensile stress is generated between the crystal grains, cracks may occur between the crystal grains depending on the metal. In particular, a Ru film is hard and easily oxidized, so that cracks between crystal grains are likely to occur. FIG. 1 is a schematic diagram showing a film state in the case of performing reduction annealing treatment after a Ru film as a metal film is formed by electroless plating. As shown in FIG. 1, cracks C occur along the crystal grain boundaries in the Ru film.

Therefore, in one embodiment, as post-treatment performed after the formation of a metal film by electroless plating, the surface of the substrate is irradiated with gas cluster ion beam generated by ionizing and accelerating clusters of atoms or molecules of an inert gas such as Ar gas or N₂ gas, and then subjected to reduction annealing treatment. By irradiating the substrate on which the metal film is formed by electroless plating with the gas cluster ion beam of the inert gas as described above, a crystalline surface-modified layer with a low oxygen concentration and a metal-rich composition is formed on the surface of the metal film. Then, by performing reduction annealing treatment in a state where the crystalline surface-modified layer is formed, crystal growth starts from the crystals of the surface-modified layer having little oxygen. This reduces oxides between crystal grains, suppresses a decrease in adhesion of crystal grains due to release of oxygen, and also suppresses tensile stress between crystal grains. Therefore, cracks at crystal grain boundaries are suppressed, and a sound, low-resistance metal film can be formed.

### <Substrate Processing Method>

Next, a substrate processing method according to one embodiment will be described in more detail.

FIG. 2 is a flowchart showing a substrate processing method according to one embodiment.

The substrate processing method of the present embodiment includes: a step of forming a metal film on a substrate by electroless plating (step ST1); a step of irradiating a surface of the substrate after the formation of the metal film with gas cluster ion beam of inert gas atoms or molecules (step ST2); and a step of performing reduction annealing on the substrate after step ST2 (step ST3).

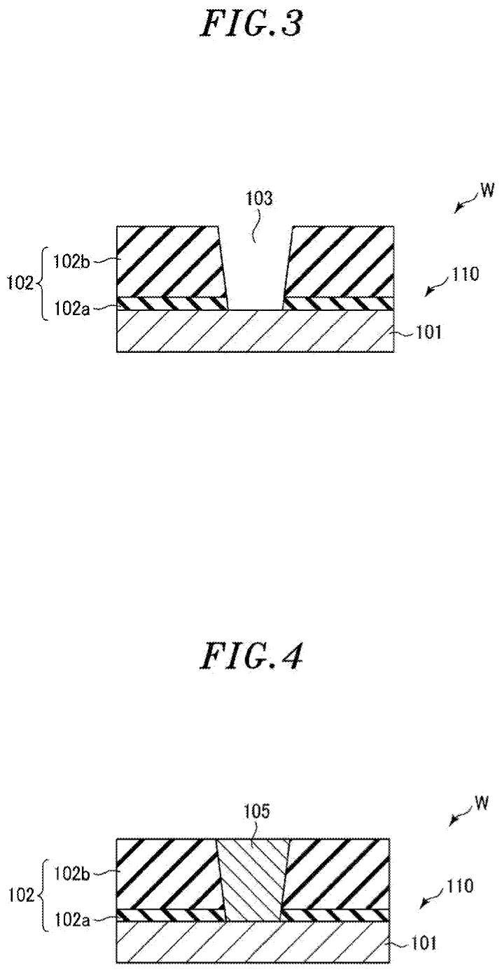

In step ST1, the substrate is not particularly limited, but a semiconductor substrate (semiconductor wafer) having a semiconductor base such as silicon may be used. For example, a substrate having a structure as shown in FIG. 3 may be used. The substrate W of FIG. 3 has a structural portion 110 provided on a Si base (not shown). The structural portion 110 has a lower wiring 101 and an insulating film 102 formed on the lower wiring 101, and a fine via 103 is formed in the insulating film 102. The lower wiring 101 is exposed at the bottom surface of the via 103. The insulating film 102 has a lower nitride film 102a and an upper oxide film 102b. Cu or Ru may preferably be used for the lower wiring 101. Alternatively, Ni or Co may also be used.

The electroless plating treatment in step ST1 is performed by applying chemical solution (plating solution) for electroless plating onto the substrate and then performing heating. A heating temperature is preferably 60 °C to 70 °C. After the heating, drying treatment is performed on the substrate.

The metal film formed by electroless plating is not particularly limited. However, when the substrate has the structure shown in FIG. 3, a metal film 105 is embedded as a wiring layer in the via 103 by performing electroless plating treatment, as shown in FIG. 4. The metal film 105 may be a Ru film, and in that case, the Ru film grows in a bottom-up manner from the bottom surface of the via 103 using the lower wiring 101 exposed at the bottom surface of the via 103 as a catalyst. Alternatively, the metal film 105 used for embedding may be a Mo film.

The structure of the substrate is not limited to that shown in FIG. 3, and the metal film is not limited to a Ru film or a Mo film. The metal constituting the metal film may be any metal that is formed as a wiring layer by electroless plating.

In step ST2, gas cluster ion beam (GCIB) is formed by adiabatically expanding a gas to generate clusters in which several to tens of thousands of atoms or molecules aggregate by Van der Waals force, ionizing the clusters, and accelerating the clusters.

In the present embodiment, an inert gas is used as a gas for generating GCIB in step ST2. The inert gas may be at least one of Ar gas or N₂ gas.

The GCIB generated by ionizing and accelerating clusters of atoms or molecules of an inert gas has high energy. By irradiating the metal film on the substrate surface with the GCIB, the irradiated portion is modified into a metal-rich crystalline layer having a low oxygen concentration by the energy of the GCIB collision. In other words, a surface-modified layer is formed on the surface of the metal film by the energy of the GCIB. The thickness of the surface-modified layer is, e.g., about 10 nm to 20 nm.

FIG. 5 is a TEM image of a Ru film in the case of irradiating a Ru film formed by electroless plating with GCIB generated using N₂ gas at an acceleration voltage of 20 KV. From FIG. 5, it is confirmed that a crystalline surface-modified layer is formed on the surface of the Ru film which is in a substantially amorphous state.

When Ar gas and N₂ gas are compared as the inert gas for forming the GCIB, Ar gas tends to have a greater modification effect, and N₂ gas tends to have higher surface smoothness. Therefore, in step ST2, when both Ar gas and N₂ gas are used as the inert gas, a sequential mode in which GCIB generated by Ar gas is irradiated first and, then, GCIB generated by N₂ gas is irradiated may be used. Accordingly, first, a process that prioritizes modification can be performed by GCIB irradiation using Ar gas and, then, a process that prioritizes surface smoothness can be performed by GCIB irradiation using N₂ gas.

When the inert gas is Ar gas, a good crack suppression effect can be obtained by setting the acceleration voltage to 17 kV or higher. When the inert gas is N₂ gas, a good crack suppression effect can be obtained by setting the acceleration voltage to 13 kV or higher. As the acceleration voltage increases, the irradiation energy of the GCIB increases, and the thickness of the surface-modified layer tends to increase. However, if the acceleration voltage is too high, the effect saturates, and sputtering may occur, which may adversely affect the surroundings during device formation. From above, the acceleration voltage for both Ar gas and N₂ gas is preferably 25 kV or less.

The step ST3 of performing reduction annealing treatment on the substrate is a step of reducing oxidized portions of the metal film and promoting crystallization of the metal film to lower the resistance of the metal film.

The reduction annealing treatment may be thermal annealing treatment or plasma annealing treatment. The thermal annealing treatment is annealing treatment in which the substrate is heated while supplying a reducing gas, and may be atmospheric-pressure treatment. The plasma annealing treatment is annealing treatment performed on the substrate by plasma of a gas containing H element, for example, H₂ gas alone or H₂ gas+inert gas, and is vacuum treatment.

When the reduction annealing treatment is thermal annealing treatment, the substrate temperature may be within a range of 200 °C to 430 °C, for example, 400 °C. The reducing gas may be a forming gas, H₂ gas, and formic acid, and at least one of them may be preferably used. The forming gas is a mixed gas of H₂ gas and N₂ gas. A gas in which the H₂ gas concentration is 5.7% or less, e.g., 4%, which is below the explosion limit, may be used as the forming gas. Although the time for the thermal annealing treatment depends on the thickness of the metal film, the time for thermal annealing treatment may be about 5 minutes to 120 minutes. Although the thermal annealing treatment is atmospheric-pressure treatment, it is preferably performed using a device having a sealed structure so that the gas composition can be maintained.

When the reduction annealing treatment is plasma annealing treatment, the treatment is performed in a vacuum atmosphere. The pressure at that time may be within a range of 100 m Torr to 2 Torr (13.3 to 266.6 Pa). The substrate temperature may be within a range of 200 °C to 430 °C, and preferably within a range of 350 °C to 400 °C. The plasma at this time is not particularly limited, and various types of plasma such as capacitively coupled plasma, inductively coupled plasma, and microwave plasma may be used.

As described above, in the present embodiment, the occurrence of cracks in the metal film is suppressed by performing the reduction annealing treatment of step ST3 after the metal film formed by electroless plating is subjected to the GCIB irradiation using atoms or molecules of the inert gas in step ST2.

In other words, by irradiating the gas cluster ion beam of atoms or molecules of the inert gas in step ST2, a crystalline surface-modified layer with a low oxygen concentration and a metal-rich composition is formed on the surface of the metal film. Thereafter, by performing the reduction annealing treatment of step ST3, crystal growth starts from the crystals of the surface layer having little oxygen. Accordingly, the decrease in adhesion of crystal grains due to the release of oxygen from oxides between crystal grains during crystal growth is suppressed. Further, since the crystal growth starts from the crystals of the surface-modified layer, large volume shrinkage does not occur, and tensile stress between crystal grains is also suppressed. Hence, cracks at crystal grain boundaries are suppressed, and a sound, low-resistance metal film can be formed.

In particular, a Ru film is expected to be a next-generation wiring material, and is prone to cracks due to reduction annealing treatment after electroless plating, so that the method of the present embodiment is effective. For example, in the case of embedding, as a wiring layer, a Ru film that is the metal film 105 in the via 103 by using a substrate having a structure in which a fine via 103 as shown in FIG. 3 is formed, it is difficult to perform voidless embedding by conventional CVD or PVD, but voidless embedding can be achieved by using electroless plating as in the present embodiment. In other words, in the case of embedding a Ru film by electroless plating, Ru selectively grows from the lower wiring 101 using the lower wiring 101 exposed at the bottom surface of the via 103 as a catalyst, and is embedded by bottom-up growth. Thus, even fine vias can be embedded voidlessly. Further, the temperature during film formation is less than 100 °C, which is low. In the present embodiment, as described above, a low-resistance Ru film can be obtained by electroless plating without generating cracks, so that the advantages of embedding Ru in vias by electroless plating can be effectively exhibited. Further, the metal film 105 may be a Mo film, which is expected to be a next-generation wiring material, similarly to a Ru film. Although a Mo film is a hard metal film and prone to cracks during reduction annealing, similarly to a Ru film, the present embodiment can suppress cracks at crystal grain boundaries and achieve low resistance.

The present embodiment is applicable not only to the selective growth from the lower wiring exposed at the bottom portion of the via as shown in FIG. 3, but also to other cases. The metal film is not limited to a Ru film or a Mo film, and may be any other metal film that can be formed by electroless plating.

### <Substrate Processing System>

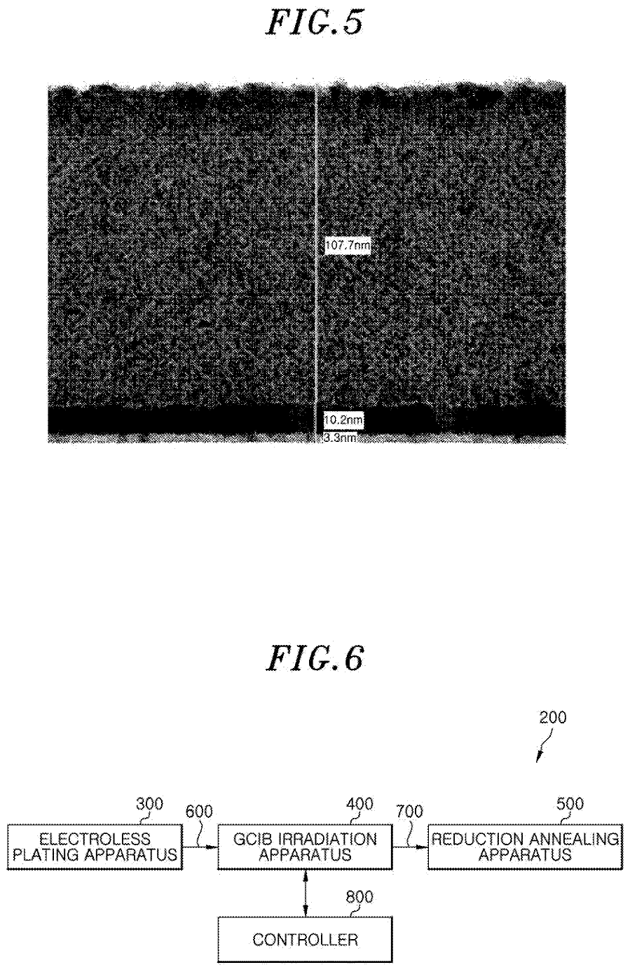

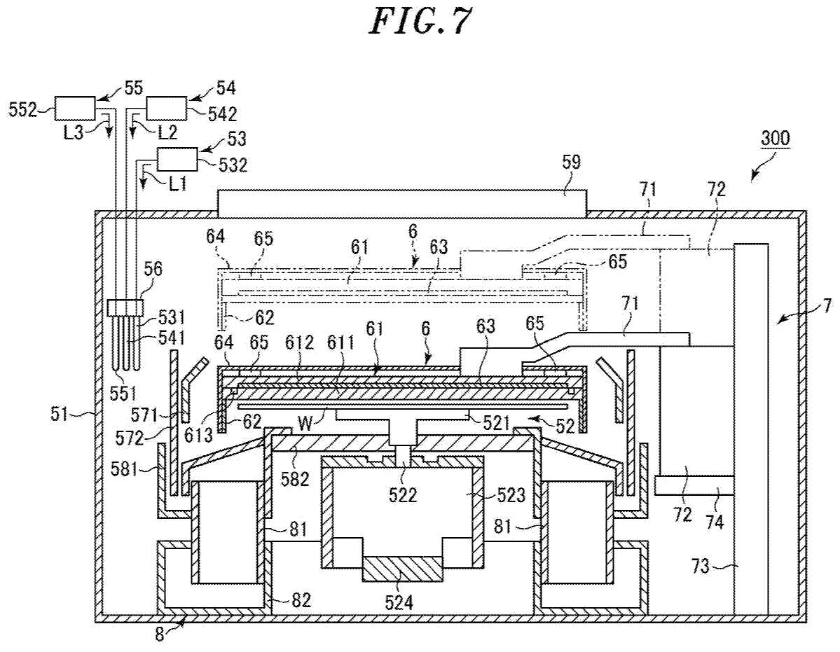

Next, a substrate processing system for performing the above-described substrate processing method will be described. FIG. 6 is a block diagram showing a substrate processing system for performing a substrate processing method according to one embodiment. Here, a case where a Ru film is used as a metal film will be described as an example.

The substrate processing system 200 includes an electroless plating apparatus 300, a GCIB irradiation apparatus 400, and a reduction annealing apparatus 500. The transfer of a substrate between the electroless plating apparatus 300 and the GCIB irradiation apparatus 400, and the transfer of a substrate between the GCIB irradiation apparatus 400 and the reduction annealing apparatus 500 are performed by substrate transfer mechanisms 600 and 700, respectively. The substrate processing system 200 further includes a controller 800 for controlling the electroless plating apparatus 300, the GCIB irradiation apparatus 400, the reduction annealing apparatus 500, and the substrate transfer mechanisms 600 and 700. They will be described individually below.

### [Electroless Plating Apparatus]

FIG. 7 is a cross-sectional view showing an example of the electroless plating apparatus 300. The electroless plating apparatus 300 forms a Ru film as a metal film by electroless plating, and includes a chamber 51, a substrate holding part 52, and a plating solution supply part 53 as shown in FIG. 7. The substrate holding part 52 is located in the chamber 51, and has a chuck member 521 for vacuum-attracting the bottom surface (backside) of the substrate W to hold the substrate W horizontally. The substrate holding part 52 may be a mechanical chuck. The plating solution supply part 53 supplies plating solution L1 to the upper surface (processing surface) of the substrate W held by the substrate holding part 52.

A rotation motor 523 is connected to the substrate holding part 52 via a rotation shaft 522. When the rotation motor 523 is driven, the substrate holding part 52 rotates together with the substrate W. The rotation motor 523 is supported by a base 524 fixed to the chamber 51.

The plating solution supply part 53 includes a plating solution nozzle 531 that injects the plating solution L1 onto the substrate W held by the substrate holding part 52, and a plating solution supply source 532 that supplies the plating solution L1 to the plating solution nozzle 531. The plating solution supply source 532 supplies the plating solution L1 of which temperature has been controlled to a predetermined temperature to the plating solution nozzle 531. The plating solution nozzle 531 is held by a nozzle arm 56, and is configured to be movable.

The plating solution L1 is, e.g., plating solution for autocatalytic (reducing) electroless plating, and contains Ru ions and a reducing agent such as hypophosphorous acid, dimethylamine borane, or hydrazine. The plating solution L1 may further contain appropriate additives. By injecting the plating solution L1 from the plating solution nozzle 531, a Ru film is applied to the upper surface of the substrate W.

The electroless plating apparatus 300 further includes, as other processing solution supply parts, a cleaning solution supply part 54 that supplies cleaning solution L2 to the upper surface of the substrate W held by the substrate holding part 52, and a rinsing solution supply part 55 that supplies rinsing solution L3 to the upper surface of the substrate W.

The cleaning solution supply part 54 includes a cleaning solution nozzle 541 that injects the cleaning solution L2 onto the substrate W held by the substrate holding part 52, and a cleaning solution supply source 542 that supplies the cleaning solution L2 to the cleaning solution nozzle 541. The cleaning solution L2 may be, e.g., organic acid or dilute hydrofluoric acid (DHF). The cleaning solution nozzle 541 is held by the nozzle arm 56 and is movable together with the plating solution nozzle 531.

The rinsing solution supply part 55 includes a rinsing solution nozzle 551 that injects the rinsing solution L3 onto the substrate W held by the substrate holding part 52, and a rinsing solution supply source 552 that supplies the rinsing solution L3 to the rinsing solution nozzle 551. The rinsing solution nozzle 551 is held by the nozzle arm 56, and is movable together with the plating solution nozzle 531 and the cleaning solution nozzle 541. The rinsing solution L3 may be, e.g., pure water.

The nozzle arm 56 holding the plating solution nozzle 531, the cleaning solution nozzle 541, and the rinsing solution nozzle 551 is configured to move in horizontal and vertical directions by a nozzle moving mechanism (not shown). The nozzle arm 56 is movable between an injection position where the plating solution L1, the cleaning solution L2, or the rinsing solution L3 is injected onto the substrate W, and a retracted position retracted from the injection position. The injection position is a position where solution can be supplied to any location on the upper surface of the substrate W. For example, the injection position is a position where solution can be supplied to the center of the substrate W. The retracted position is located outside the substrate W.

A cup 571 is provided around the substrate holding part 52. The cup 571, which is formed in a ring shape, receives solution scattered from the substrate W during the rotation of the substrate W and guides the solution to a drain duct 581 to be described later. An atmosphere blocking cover 572 is provided on the outer peripheral side of the cup 571 to suppress diffusion of the atmosphere around the substrate W into the chamber 51. The atmosphere blocking cover 572 is formed in a cylindrical shape extending in the vertical direction, and has an open upper end. A lid 6 to be described later can be inserted from above into the atmosphere blocking cover 572.

A drain duct 581 is provided below the cup 571. The drain duct 581, which is formed in a ring shape, receives and discharges solution that has been received by the cup 571 and has flowed downward or processing solution that has directly flowed downward from the periphery of the substrate W. An inner cover 582 is provided on the inner peripheral side of the drain duct 581.

The upper surface of the substrate W held by the substrate holding part 52 is covered by the lid 6. The lid 6 includes a ceiling portion 61 extending in the horizontal direction, and a sidewall portion 62 extending downward from the ceiling portion 61. When the lid 6 is located at a lower position (i.e., processing position) to be described later, the ceiling portion 61 faces the substrate W held by the substrate holding part 52 at a relatively close distance.

The ceiling portion 61 includes a first ceiling plate 611 and a second ceiling plate 612 provided on the first ceiling plate 611. The first ceiling plate 611 and the second ceiling plate 612 are provided with a heater 63 interposed therebetween. A seal ring 613 is provided on the outer peripheral side of the heater 63 between the first ceiling plate 611 and the second ceiling plate 612, thereby sealing the heater 63 and preventing the heater 63 from being in contact with solution such as the plating solution L1 or the like. The first ceiling plate 611 and the second ceiling plate 612 may be made of a material having corrosion resistance against solution such as the plating solution L1, for example, an aluminum alloy. In order to further enhance corrosion resistance, the first ceiling plate 611, the second ceiling plate 612, and the sidewall portion 62 may be coated with Teflon (Registered Trademark).

The lid 6 is connected to a lid moving mechanism 7 via a lid arm 71. The lid moving mechanism 7 includes a swing motor 72 that moves the lid 6 in the horizontal direction and a cylinder 73 that moves the lid 6 in the vertical direction. The swing motor 72 is mounted on a support plate 74 capable of moving in the vertical direction with respect to the cylinder 73.

The swing motor 72 of the lid moving mechanism 7 moves the lid 6 between an upper position (indicated by dashed double-dotted lines in FIG. 7) located above the substrate W held by the substrate holding part 52, and a retracted position (not shown) retracted from the upper position. The retracted position is located outside the substrate W in the chamber 51. The rotation axis of the swing motor 72 extends in the vertical direction, and the lid 6 is horizontally pivotable between the upper position and the retracted position.

The cylinder 73 of the lid moving mechanism 7 moves the lid 6 between a lower position (indicated by solid lines in FIG. 7), which is a processing position, and the upper position, thereby adjusting the gap between the substrate W on which the plating solution L1 is loaded and the first ceiling plate 611 of the ceiling portion 61. When the lid 6 is located at the lower position, the first ceiling plate 611 becomes close to the substrate W.

When the lid 6 is located at the above-described lower position, the plating solution L1 on the substrate W is heated by the heater 63.

The sidewall portion 62 of the lid 6 extends downward from the peripheral edge of the first ceiling plate 611 of the ceiling portion 61, and is located on the outer peripheral side of the substrate W when the lid 6 is located at the lower position to heat the plating solution L1 on the substrate W.

The ceiling portion 61 and the sidewall portion 62 of the lid 6 are covered by a lid cover 64. The lid cover 64 is placed on the second ceiling plate 612 of the lid 6 via a plurality of support portions 65. The lid cover 64 is preferably made of a material having heat insulation properties higher than those of the ceiling portion 61 and the sidewall portion 62, such as a resin material, in order to suppress heat in the lid 6 from escaping to the surroundings.

A fan filter unit 59 for supplying clean air around the lid 6 is provided at the upper portion of the chamber 51. The fan filter unit 59 supplies air into the chamber 51 (particularly into the atmosphere blocking cover 572). The supplied air flows toward exhaust lines 81 to be described later. Downward airflow is formed around the lid 6, and gas vaporized from the processing solution such as the plating solution L1 flows toward the exhaust lines 81 by the downward airflow. Accordingly, the gas vaporized from the processing solution is prevented from rising and diffusing into the chamber 51.

The gas supplied from the fan filter unit 59 as described above is discharged by an exhaust mechanism 8. The exhaust mechanism 8 includes two exhaust lines 81 provided below the cup 571, and an exhaust duct 82 provided below the drain duct 581. The two exhaust lines 81 penetrate through the bottom portion of the drain duct 581 and communicate with the exhaust duct 82. The exhaust duct 82 is formed in a substantially semi-circular ring shape when viewed from above. One exhaust duct 82 is provided below the drain duct 581, and the two exhaust lines 81 communicate with the exhaust duct 82.

In the electroless plating apparatus 300 configured as described above, first, in a state where clean air is supplied into the chamber 51 from the fan filter unit 59, the substrate W is loaded into the electroless plating apparatus 300 and horizontally held by the substrate holding part 52.

Next, a cleaning process of the substrate W held by the substrate holding part 52 is performed. In the cleaning process, the substrate W is rotated at a predetermined rotational speed by the rotation motor 523, the nozzle arm 56 is moved from the retracted position to the discharge position, and the cleaning solution L2 is supplied from the cleaning solution nozzle 541 to the upper surface of the rotating substrate W. As a result, the surface of the substrate W is cleaned, and deposits and the like are removed. The cleaning solution L2 supplied to the substrate W is discharged to the drain duct 581.

Then, a rinse process of the substrate W is performed. In the rinse process, the rinsing solution L3 is supplied from the rinsing solution nozzle 551 to the rotating substrate W to rinse the surface of the substrate W. As a result, the cleaning solution L2 remaining on the substrate W is washed away. The rinsing solution L3 supplied to the substrate W is discharged to the drain duct 581.

Next, the plating solution L1 is supplied to the upper surface of the substrate W held by the substrate holding part 52 to form a puddle of the plating solution L1 on the upper surface of the substrate W. In forming the puddle on the upper surface of the substrate W, first, the plating solution L1 is injected from the plating solution nozzle 531 onto the upper surface of the substrate W while the substrate W is rotated at a rotational speed lower than that during the rinse process. The plating solution L1 remains on the upper surface due to surface tension, thereby forming a layer of the plating solution L1, i.e., a so-called puddle. A part of the plating solution L1 flows out from the upper surface and is discharged through the drain duct 581. After a predetermined amount of the plating solution L1 is injected from the plating solution nozzle 531, the injection of the plating solution L1 is stopped. Thereafter, the nozzle arm 56 is retracted to the retracted position. By forming the puddle while rotating the substrate W, the plating film can become uniform. Alternatively, the rotation of the substrate W may be stopped to increase the amount of the plating solution L1 loaded on the surface.

Next, a process of heating the plating solution L1 loaded on the substrate W is performed. The plating solution heating process includes an operation of covering the substrate W with the lid 6, an operation of supplying an inert gas, an operation of locating the lid 6 at the lower position that is the processing position to actually heat the plating solution L1, and an operation of retracting the lid 6 from a position above the substrate W. During the heating of the plating solution L1, it is preferable that the rotational speed of the substrate W (including the case where the rotation is stopped) is maintained at the same level as that during the loading of the plating solution.

The operation of supplying the inert gas is performed to supply an inert gas into the space between the substrate W held by the substrate holding part 52 and the lid 6 located at the lower position, and performing the plating process on the upper surface of the substrate W while maintaining a low-oxygen atmosphere around the substrate W.

When the temperature of the plating solution L1 increases, due to the actual heating operation, to a temperature at which components in the plating solution L1 precipitate, the components of the plating solution L1 precipitate on the upper surface of the substrate W and, thus, a plating film (Ru film) is formed and grows. The heating operation is performed while maintaining the temperature of the plating solution L1 at a temperature at which the plating film precipitates, for example, 50 °C to 85 °C, for a period of time required to obtain a plating film of a desired thickness.

Next, a rinse process of the substrate W is performed. In the rinse process, first, the rotational speed of the substrate W is set to be higher than the rotation speed during the plating process (puddle formation and heating), and the substrate W is rotated at the same rotation speed as that in the substrate rinsing process before the plating process. Next, the rinsing solution nozzle 551 is moved from the retracted position to the injection position. Then, the rinsing solution L3 is supplied from the rinsing solution nozzle 551 to the rotating substrate W to wash away the plating solution L1 remaining on the substrate W.

Thereafter, a drying process of the substrate W is performed. In the drying process, the substrate W is rotated at a high speed to spin off and dry the rinsing solution L3 remaining on the substrate W. Accordingly, a substrate having a Ru film that is a dried electroless plating film is obtained. In this case, drying may be promoted by injecting an inert gas such as N₂ gas onto the substrate W.

Then, the substrate W is taken out from the substrate holding part 52 and unloaded from the electroless plating apparatus 300.

In actual cases, a plurality of electroless plating apparatuses 300 are arranged and configured as a unit. In other words, for example, a plurality of electroless plating apparatuses 300, a loading/unloading station for loading/unloading the substrate W, and a transfer mechanism are integrated into a unit. A substrate is transferred by the transfer mechanism from a substrate storage container, which stores a plurality of substrates arranged in the loading/unloading station, to one of the electroless plating apparatuses 300, and is processed by the electroless plating apparatus 300.

### [GCIB Irradiation Apparatus]

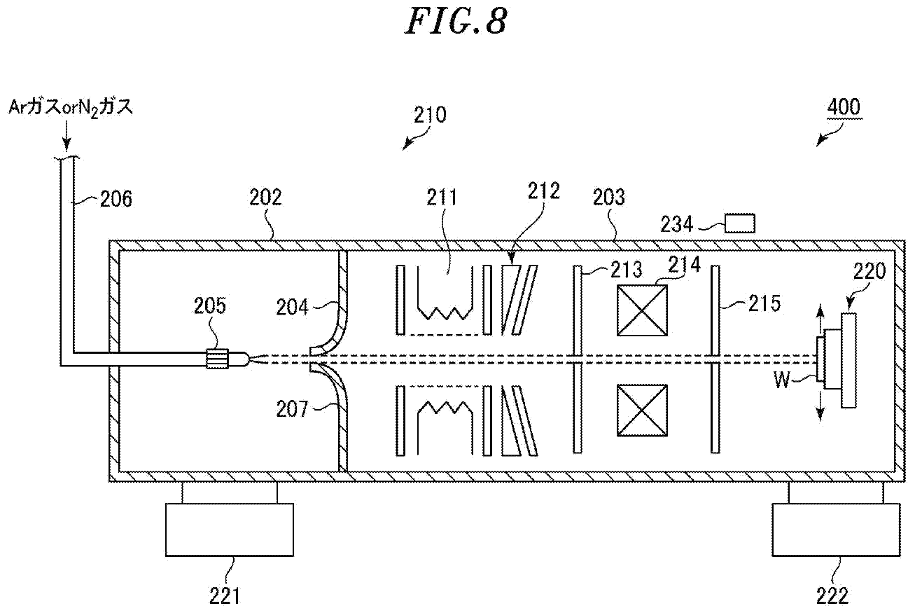

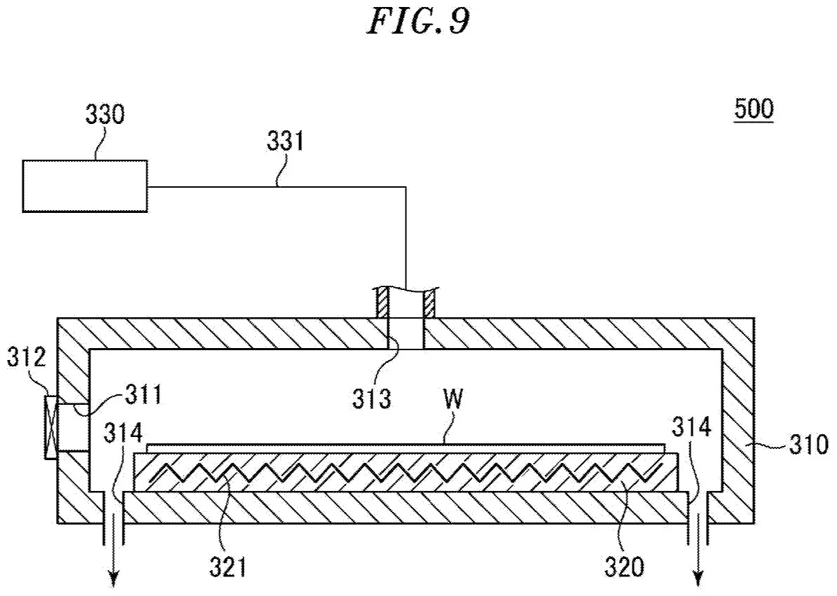

FIG. 8 is a cross-sectional view showing an example of the GCIB irradiation apparatus 400. The GCIB irradiation apparatus 400 irradiates a substrate W on which a Ru film has been formed by electroless plating with GCIB of inert gas atoms or molecules to form a surface-modified layer by GCIB on the surface of the Ru film.

The GCIB irradiation apparatus 400 includes a source chamber 202 in which an inert gas serving as a source gas, for example, Ar gas or N₂ gas, is injected to form cluster flow, and a target chamber 203 in which the cluster flow formed in the source chamber 202 is irradiated as cluster beam onto a substrate W that is a target. The source chamber 202 and the target chamber 203 are partitioned by a partition wall 204.

A nozzle 205 for injecting inert gas flow and clustering it is provided in the source chamber 202. A nozzle line 206 is connected to the nozzle 205, and an inert gas is supplied to the nozzle line 206 from a gas source (not shown) outside the source chamber 202. The pressure of the inert gas injected from the nozzle 205 is controlled by a regulator (not shown). The inert gas in this jet undergoes adiabatic expansion, and several to several tens of thousands of atoms or molecules (Ar gas atoms or N₂ gas molecules) aggregate due to Van der Waals force to form clusters, thereby forming cluster flow.

A skimmer 207 is provided in the source chamber 202 to face the nozzle 205. The skimmer 207 is provided on the partition wall 204 to protrude toward the nozzle 205 side, and has an aperture through which the cluster flow injected from the nozzle 205 passes so as to prevent shock waves.

The cluster flow is introduced into the target chamber 203 through the aperture of the skimmer 207. An ionizer 211 including a plurality of annular electrodes is provided along the cluster flow to ionize the cluster flow. An accelerator 212 for applying an acceleration voltage (bias voltage) and accelerating the ionized cluster flow is provided on the downstream side of the ionizer 211. Thus, the cluster flow is ionized by the ionizer 211 and accelerated by the accelerator 212, and become GCIB.

A first aperture 213, a permanent magnet 214, and a second aperture 215 are provided on the downstream side of the accelerator 212. By adjusting the diameter of GCIB with the first aperture 213 and the second aperture 215, and bending the trajectories of particles of small mass, such as monomer ions or small cluster particles, with the permanent magnet 214, only GCIB of appropriate size passes through the second aperture 215.

The GCIB is formed by the nozzle 205, the nozzle line 206, the skimmer 207, the ionizer 211, the accelerator 212, the first aperture 213, the permanent magnet 214, the second aperture 215, and the like.

An X-Y stage 220 that holds the substrate W having a Ru film as a metal film on its surface, and scans the substrate W two-dimensionally is located on the downstream side of the second aperture 215. The substrate W is loaded and unloaded through a loading/unloading port (not shown) provided in the target chamber 203, and the loading/unloading port can be opened and closed by a gate valve (not shown). The substrate W used in this case may be, e.g., a semiconductor substrate (semiconductor wafer) having a structure shown in FIG. 4, but is not limited thereto.

Vacuum pumps 221 and 222 are provided in the source chamber 202 and the target chamber 203, respectively. The insides of the source chamber 202 and the target chamber 203 are set to a predetermined depressurized (vacuum) state by evacuating them with the vacuum pumps 221 and 222.

The pressure in the region where the substrate is located in the target chamber 203 is measured by a pressure gauge 234, and is controlled by an automatic pressure control valve (not shown) connected to the vacuum pump 222 such that the pressure measured by the pressure gauge 234 becomes a predetermined value.

In the GCIB irradiation apparatus 400 configured as described above, first, a gate valve (not shown) of the target chamber 203 is opened, and the substrate W is loaded from the loading/unloading port (not shown) and held on the X-Y stage 220. In this state, the source chamber 202 and the target chamber 203 are evacuated by the vacuum pumps 221 and 222 to achieve a high vacuum state.

Then, an inert gas is injected from the nozzle 205 in the source chamber 202 to form cluster flow. The cluster flow is ionized by the ionizer 211 and accelerated by the accelerator 212 to form GCIB, and the GCIB is irradiated onto the substrate W supported on the X-Y stage 220. At this time, by scanning the substrate W with the X-Y stage 220, the GCIB scans over the substrate W.

In forming the GCIB, the cluster flow supplied from the source chamber 202 to the target chamber 203 is ionized by the ionizer 211 and accelerated by the accelerator 212. The accelerator 212 accelerates the ionized clusters by applying an acceleration voltage (bias voltage). As the acceleration voltage increases, the GCIB is more accelerated. The GCIB thus formed has an adjusted beam diameter while passing through the first and second apertures 213 and 215, and particles of small mass are removed from the beam path by the permanent magnet 214, resulting in an appropriately controlled cluster size. The GCIB having a beam diameter and a cluster size controlled as described above is irradiated onto the substrate W.

When the substrate W is irradiated with the GCIB of the inert gas, the GCIB collides with the Ru film, which is a metal film formed on the substrate surface, and the collision portion is modified by the collision energy into a crystalline layer with a low oxygen concentration and a Ru-rich composition. In other words, a crystalline surface-modified layer with a low oxygen concentration and a Ru-rich composition is formed on the surface of the Ru film that is a metal film. The acceleration voltage of the GCIB at this time is preferably 17 kV or more when the inert gas is Ar gas, and preferably 13 kV or more when the inert gas is N₂ gas. Although a higher acceleration voltage enables formation of a thicker surface-modified layer, if the acceleration voltage is excessively high, the effect saturates and the sputtering effect also increases. Therefore, the acceleration voltage is preferably 25 kV or less.

### [Reduction Annealing Apparatus]

FIG. 9 is a cross-sectional view showing an example of the reduction annealing apparatus 500. The reduction annealing apparatus 500 includes a processing chamber 310, a heating plate 320, and a gas supply part 330.

The processing chamber 310 is a substantially sealed cylindrical metal container, and the inside thereof is maintained at an atmospheric pressure. A heating plate 320 is provided at the center of the bottom portion in the processing chamber 310. A loading/unloading port 311 for loading/unloading the substrate W is formed in the sidewall of the processing chamber 310. The loading/unloading port 311 is opened and closed by a shutter 312. A gas inlet port 313 for introducing a reducing gas is formed at the center of the ceiling wall of the processing chamber 310, and a plurality of exhaust ports 314 are formed outside the heating plate 320 at the bottom wall.

The heating plate 320 is made of a metal and heats the substrate W placed on its upper surface. A heater 321 is embedded in the heating plate 320. The heater 321 heats the heating plate 320 such that the temperature of the substrate W placed thereon becomes 200 °C to 430 °C, for example, 400 °C.

The gas supply part 330 supplies a reducing gas into the processing chamber 310 through a line 331 and the gas inlet port 313. The reducing gas may be a forming gas, H₂ gas, formic acid, or the like.

In the reduction annealing apparatus 500 configured as described above, first, the substrate W that has been processed by the GCIB irradiation apparatus 400 is loaded into the processing chamber 310 and placed on the heating plate 320 by a transfer mechanism (not shown). At this time, the temperature of the heating plate 320 is controlled by the heater 321 such that the temperature of the placed substrate W becomes 200 °C to 430 °C, for example, 400 °C.

Next, a reducing gas is supplied from the gas supply part 330 into the processing chamber 310, and reduction annealing treatment is performed on the substrate W on the heating plate 320. As a result, oxidized portions of the Ru film are reduced, and crystallization of the Ru film is promoted, thereby lowering the resistance of the Ru film. The processing time at this stage may be about 5 min to 120 min.

After supplying the reducing gas for a predetermined period of time, the supply of the reducing gas is stopped, and the substrate on the heating plate 320 is unloaded from the processing chamber 310 by a transfer mechanism (not shown).

The reduction annealing apparatus 500 is actually incorporated into a system configured in such a manner that a substrate is transferred from a substrate storage container located at a loading/unloading station to the reduction annealing apparatus 500 by a transfer mechanism.

In the above example, the apparatus configured to perform thermal annealing at an atmospheric pressure while supplying a reducing gas has been described as the reduction annealing apparatus 500. However, an apparatus configured to perform plasma annealing on the substrate using plasma of a gas containing hydrogen elements may be used as the reduction annealing apparatus 500. As the apparatus configured to perform plasma annealing, it is possible to use an apparatus in which a substrate is placed on a substrate placing table in a processing chamber, the inside of the chamber is set to a depressurized (vacuum) state, a gas containing hydrogen elements such as H₂ gas or H₂ gas+inert gas is supplied from the gas supply part, and high-frequency electric field is generated between the substrate placing table and the upper electrode to generate plasma.

In the case where atmospheric-pressure treatment is performed using the reduction annealing apparatus 500 that performs thermal annealing, it is necessary to restore the pressure to an atmospheric pressure after the processing is performed by the GCIB irradiation apparatus 400 in a vacuum state. In contrast, when the reduction annealing treatment is plasma annealing, which is vacuum treatment, it is possible to perform the GCIB irradiation treatment and the hydrogen plasma treatment in situ, which is efficient.

### [Substrate Transfer Mechanism]

The substrate transfer mechanisms 600 and 700 transfer multiple substrates stored in a substrate storage container between the electroless plating apparatus 300 and the GCIB irradiation apparatus 400, and between the GCIB irradiation apparatus 400 and the reduction annealing apparatus 500, respectively. It is preferable that the substrate storage container is transferred while being maintained in a non-oxidizing atmosphere such as an inert atmosphere or a reducing atmosphere so as to suppress oxidation of the Ru film formed by electroless plating.

### [Controller]

The controller 800 controls individual components of the substrate processing system 200, such as the electroless plating apparatus 300, the GCIB irradiation apparatus 400, the reduction annealing apparatus 500, and the substrate transfer mechanisms 600 and 700. The controller 800 includes a main controller having a CPU (computer), an input device, an output device, a display device, and a storage device. The main controller of the controller 800 causes the substrate processing system 200 to execute desired operations based on, e.g., a processing recipe stored in a storage medium built in the storage device or set in the storage device.

In the substrate processing system 200, under the control of the controller 800, the electroless plating apparatus 300, the GCIB irradiation apparatus 400, and the reduction annealing apparatus 500 having the above configurations are operated as described above, thereby realizing a substrate processing method according to one embodiment.

### Test Example

Next, a test example will be described.

Here, after forming a Ru film as a metal film by electroless plating, a process of irradiating GCIB under various conditions was performed. Then, a film state and a resistivity were evaluated for samples that have been subjected to reduction annealing treatment. The reduction annealing treatment was carried out at 400 °C for 10 minutes using a forming gas (H₂ gas concentration: 4%). In the process of irradiating GCIB, Ar gas or N₂ gas was used as the inert gas. In the case of Ar gas, the acceleration voltage was varied to 9 kV, 13 KV, 17 KV, 20 KV, 25 kV, and 30 kV. In the case of N₂ gas, the acceleration voltage was varied to 5 kV, 13 KV, 17 kV, 20 KV, 25 KV, and 30 kV. For comparison, the film state and the resistivity were also evaluated for a sample that has been subjected to reduction annealing under the same conditions without performing the process of irradiating GCIB after forming a Ru film by electroless plating.

As a result, in the comparative sample in which the process of irradiating GCIB was not performed, the resistivity was 18.5 μΩ·cm, and cracks were observed in the film. The resistivity and the presence or absence of film cracks, which were obtained when the reduction annealing was performed after the process of irradiating GCIB using Ar gas, and when the reduction annealing was performed after the process of irradiating GCIB using N₂ gas, are shown in Tables 1 and 2, respectively.

TABLE 1
Ar gas

| acceleration | resistivity | |
|---|---|---|
| voltage (kV) | (μΩ · cm) | presence or absence of cracks |
| 9 | 15 | slightly present |
| 13 | 11.9 | slightly present |
| 17 | 11.7 | absent |
| 20 | 16.3 | absent |
| 25 | 15.8 | absent |
| 30 | 18.5 | absent |

TABLE 2
N₂ gas

| acceleration | resistivity | |
|---|---|---|
| voltage (kV) | (μΩ · cm) | presence or absence of cracks |
| 5 | 21.4 | present (hardly improved) |
| 13 | 15.8 | absent |
| 17 | 17.3 | absent |
| 20 | 18.8 | absent |
| 25 | 15.8 | absent |
| 30 | 16.6 | absent (effects tend to saturate) |

In other words, when the reduction annealing treatment was performed after the process of irradiating GCIB using Ar gas, as shown in Table 1, the improvement in resistivity was observed at acceleration voltages of 9 kV and 13 kV, but a small amount of cracks remained in the film. At acceleration voltages of 17 kV to 25 kV, the resistivity was lower than that of the comparative sample, and no cracks were observed in the film. At an acceleration voltage of 30 kV, the resistivity was substantially the same as that of the comparative sample, but no cracks were observed. When reduction annealing treatment was performed after the process of irradiating GCIB using N₂ gas, as shown in Table 2, no improvement in resistivity was observed at an acceleration voltage of 5 kV, and cracks in the film were hardly improved. At acceleration voltages of 13 kV to 25 kV, the resistivity was improved in many samples, and no cracks were observed in the film. At an acceleration voltage of 30 kV, the resistivity was 16.6 μΩ·cm and no cracks were observed, but there was a tendency for saturation of the effect.

### <Other Applications>

While the embodiments of the present disclosure have been described, it should be noted that the embodiments of the present disclosure are illustrative in all respects and are not restrictive. The above-described embodiments may be omitted, replaced, or changed in various forms without departing from the scope of the appended claims and the gist thereof.

For example, the electroless plating apparatus in the above embodiment is merely illustrative, and various other apparatus configurations may be used. The GCIB irradiation apparatus is also merely illustrative, and the apparatus configuration is not limited as long as clusters of inert gas atoms or molecules can be generated, ionized, accelerated, and irradiated as GCIB onto the substrate. The reduction annealing apparatus in the above embodiment is merely illustrative, and any apparatus capable of performing thermal annealing treatment or plasma annealing treatment may be used.

In the above embodiment, the case in which a Ru film is formed as a metal film on the substrate shown in FIG. 3 and is selectively grown in a bottom-up manner from the lower wiring at the bottom of the via has been illustrated. However, the structure of the substrate is not limited to that shown in FIG. 3, and the metal constituting the metal film may be any metal that is formed as a wiring layer by electroless plating.

Further, although the case of using the semiconductor substrate (semiconductor wafer) having a semiconductor base as the substrate has been described, the substrate is not limited to the semiconductor wafer and may be another type of substrate such as a flat panel display (FPD) substrate or a ceramic substrate.

1. A substrate processing method comprising:
forming a metal film on a substrate by electroless plating;
irradiating a surface of the substrate on which the metal film is formed with gas cluster ion beam generated by ionizing and accelerating clusters of atoms or molecules of an inert gas; and
performing reduction annealing treatment on the substrate after said irradiating the substrate with the gas cluster ion beam.

2. The substrate processing method of claim 1, wherein when the surface of the metal film is irradiated with the gas cluster ion beam, a crystalline surface-modified layer with a low oxygen concentration and a metal-rich composition is formed on the surface of the metal film.

3. The substrate processing method of claim 1, wherein the metal film is a Ru film or a Mo film.

4. The substrate processing method of claim 1, wherein the substrate includes a lower wiring, an insulating film formed on the lower wiring, and a via formed in the insulating film to expose the lower wiring at a bottom surface, and
the metal film is embedded in the via.

5. The substrate processing method of claim 4, wherein the metal film is a Ru film, and the Ru film grows in a bottom-up manner in the via from the lower wiring using the lower wiring as a catalyst.

6. The substrate processing method of claim 1, wherein in said irradiating the substrate with the gas cluster ion beam, at least one of Ar gas or N₂ gas as the inert gas is used.

7. The substrate processing method of claim 6, wherein the inert gas is Ar gas, and an acceleration voltage for generating the gas cluster ion beam is 17 kV or more.

8. The substrate processing method of claim 6, wherein the inert gas is N₂ gas, and an acceleration voltage for generating the gas cluster ion beam is 13 kV or more.

9. The substrate processing method of claim 6, wherein said irradiating the substrate with the gas cluster ion beam includes irradiating the gas cluster ion beam using Ar gas as the inert gas, and then irradiating the gas cluster ion beam using N₂ gas as the inert gas.

10. The substrate processing method of claim 1, wherein said forming the metal film by electroless plating includes applying an electroless plating solution onto the substrate, heating the substrate to precipitate a plating film to become the metal film, and drying the substrate.

11. The substrate processing method of claim 1, wherein said performing reduction annealing treatment on the substrate is carried out by performing thermal annealing on the substrate at an atmospheric pressure while supplying a reducing gas.

12. The substrate processing method of claim 1, wherein said performing reduction annealing treatment on the substrate is carried out by performing plasma annealing on the substrate using plasma of a gas containing hydrogen elements.

13. A substrate processing system comprising:
an electroless plating apparatus configured to form a metal film on a substrate by electroless plating;
a gas cluster ion beam irradiation apparatus configured to irradiate a surface of the substrate, on which the metal film is formed by the electroless plating apparatus, with gas cluster ion beam formed by ionizing and accelerating clusters of atoms or molecules of an inert gas; and
a reduction annealing apparatus configured to perform reduction annealing treatment on the substrate irradiated with the gas cluster ion beam by the gas cluster ion beam irradiation apparatus.

14. The substrate processing system of claim 13, wherein the gas cluster ion beam irradiation apparatus irradiates the surface of the metal film with the gas cluster ion beam, thereby forming a crystalline surface-modified layer with a low oxygen concentration and a metal-rich composition on the surface of the metal film.

15. The substrate processing system of claim 13, wherein the gas cluster ion beam irradiation apparatus uses at least one of Ar gas or N₂ gas as the inert gas for generating the gas cluster ion beam.

16. The substrate processing system of claim 15, wherein the inert gas is Ar gas, and an acceleration voltage for generating the gas cluster ion beam is 17 kV or more.

17. The substrate processing system of claim 15, wherein the inert gas is N₂ gas, and an acceleration voltage for generating the gas cluster ion beam is 13 kV or more.

18. The substrate processing system of claim 13, wherein the reduction annealing apparatus is an apparatus configured to perform thermal annealing on the substrate at an atmospheric pressure while supplying a reducing gas.

19. The substrate processing system of claim 13, wherein the reduction annealing apparatus is a plasma annealing apparatus configured to process the substrate using plasma of a gas containing hydrogen elements.
